(19) United States
(12) Patent Application Publication
(10) Pub. No.: US 2009/0047796 A1
(43) Pub. Date: Feb. 19, 2009

(54) Method of Manufacturing a Dielectric Layer having Plural High-K Films

(75) Inventors: Chen-Hua Yu, Hsin-Chu (TW); Liang-Gi Yao, Shin-Chu (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: TAIWAN SEMICONDUCTOR MANUFACTURING CO., LTD., Hsin-Chu (TW)

(21) Appl. No.: 11/837,652

(22) Filed: Aug. 13, 2007

(51) Int. Cl. H01L 21/31

(52) U.S. Cl. 438/761; 257/E21.241

(57) ABSTRACT

Nitridizing and optionally annealing plural high-k films layer-by-layer are performed to dope nitrogen into high-k films.

### BACKGROUND

1. Field of Invention

The present invention relates to a semiconductor process. More particularly, the present invention relates to a method of manufacturing a dielectric layer.

2. Description of Related Art

Doping nitrogen into a dielectric film having a high dielectric constant (high-k) can prevent crystallization of the high-k films, reduce the equivalent of oxide thickness (EOT) and prevent boron penetration effectively, and the performance of semiconductor device can be thus improved.

Conventional method of doping nitrogen into a high-k film is performed by either thermal nitridation or plasma nitridation. The frequently occurred problem of the thermal nitridation is overdoping nitrogen into the interface between the high-k film and the substrate. The frequently occurred problem of the plasma nitridation includes plasma damage to the high-k film and too many unreactive bondings.

### SUMMARY

Nitridizing and optionally annealing plural high-k films layer-by-layer is performed to dope nitrogen into high-k films.

### BRIEF DESCRIPTION OF THE DRAWINGS

The invention can be more fully understood by reading the following detailed description of the embodiments, with reference made to the accompanying drawings as follows:

FIGS. 1A-1C are cross-sectional diagrams showing manufacturing a dielectric layer having plural high-k films according to an embodiment of this invention; and

FIG. 2 is a process flow diagram according to an embodiment of this invention.

### DETAILED DESCRIPTION

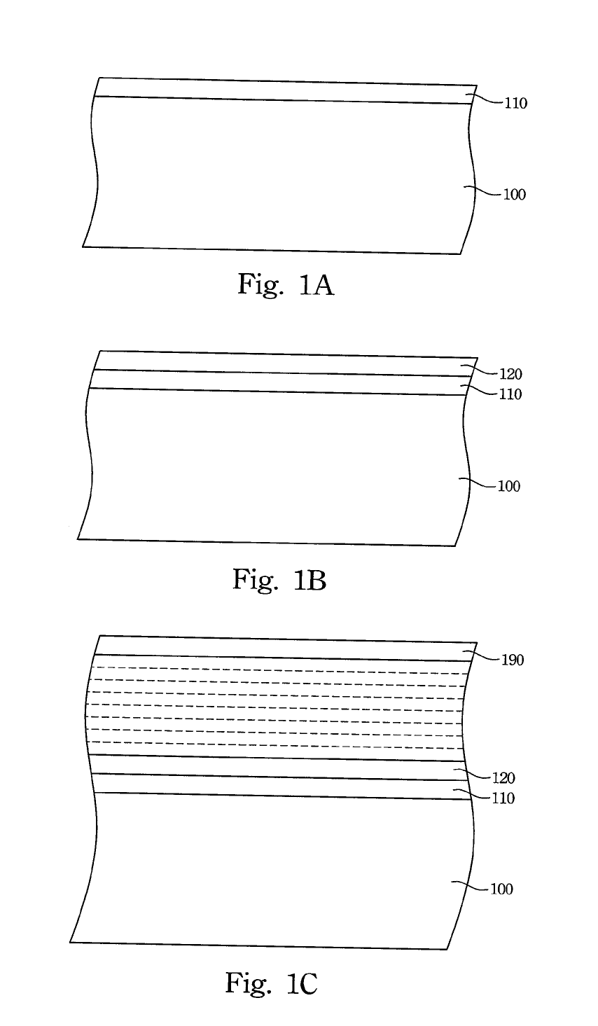

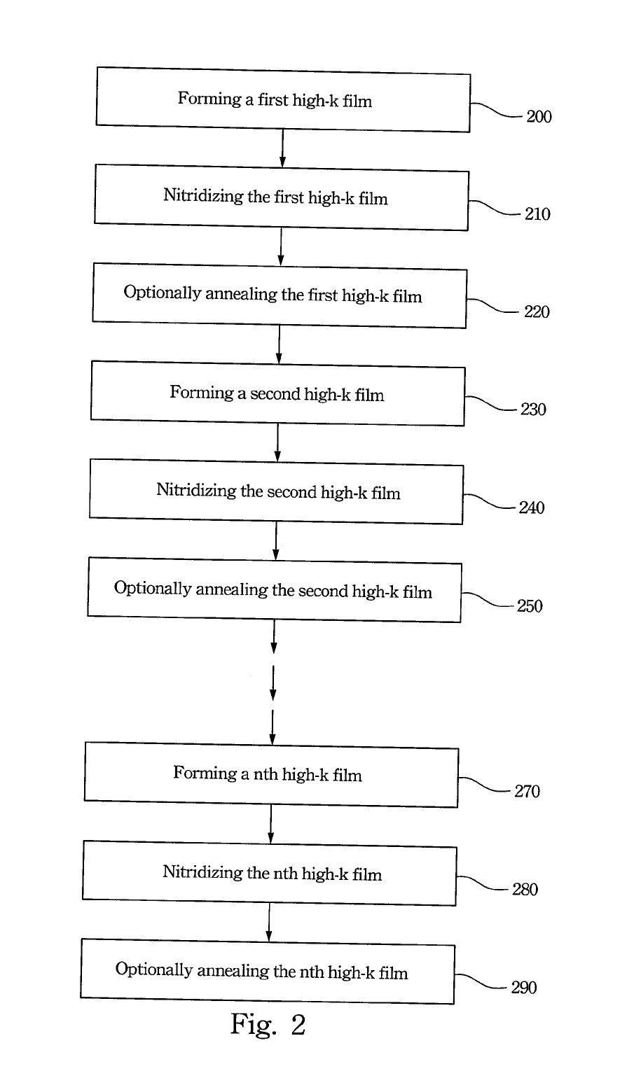

FIGS. 1A-1C are cross-sectional diagrams showing manufacturing a dielectric layer having plural high-k films according to an embodiment of this invention; and FIG. 2 is a process flow diagram according to an embodiment of this invention. Please refer to FIGS. 1A-1C and FIG. 2 at the same time.

In FIG. 1A and FIG. 2, a step 200 is performed to form a first high-k film 110 on a substrate 100. A step 210 is next performed to nitridize the first high-k film 110 by low-power plasma. Then, a step 220 is optionally performed to anneal the first high-k film 110.

In FIG. 1B and FIG. 2, a step 230 is performed to form a second high-k film 120 on the first high-k film 110. A step 240 is next performed to nitridize the second high-k film 120 by low-power plasma. Then, a step 250 is optionally performed to anneal the second high-k film 120.

The steps of forming a high-k film, nitridizing the high-k film, and optionally annealing the high-k film are repeated for several times according to the process demand.

Finally, in FIG. 1C and FIG. 2, a step 270 is performed to form an nth high-k film 190. A step 280 is next performed to nitridize the nth high-k film 190 by low-power plasma. Then, a step 290 is optionally performed to anneal the second high-k film 190. The first high-k film 110, the second high-k film 120, . . . , and the nth high-k film 190 compose a dielectric layer needed by the process.

Each of these high-k films (110, 120, . . . , and 190) has various thickness of about 0.5 nm to about 2.0 nm. The material of these high-k films (110, 120, . . . , and 190) can be any silicate material or rare earth metal oxide, such as HfSiOx, HfO₂, Ta₂O₅, ZrO₂, or HfZrOₓ, HfLaOx, HfDyOx, HfScOx.

The substrate 100 above is maintained at a higher temperature for nitridation. According to an embodiment of this invention, the temperature of the substrate is maintained at a temperature higher than about 60° C., such as about 60° C. to about 300° C.

The pressure in the reactive chamber for nitridizing these high-k films (110, 120, . . . , and 190) is about 1 mTorr to about 1 Torr. The RF power of the low-power plasma above is about 200 W to 2000 W depends on the operation mode. For example, when the low-power plasma is applied in a continuous mode or in a pulse mode.

These high-k films (110, 120, . . . , and 190) are annealed under a dilute oxygen ambient having an oxygen concentration of less than 2% or in an inert ambient (e.g. N₂). The temperature of annealing these high-k films (110, 120, . . . , and 190) is about 600° C. to about 1200° C. for about 10-3 seconds to about 1 hour depends on the method used. For example, when these high-k films (110, 120, . . . , and 190) are annealed by rapid thermal annealing, the annealing temperature ranges from about 600° C. to about 1050° C. with the duration ranging from 0.1 sec to 100 sec. When these high-k films (110, 120, . . . , and 190) are annealed by flash annealing, the annealing temperature ranges from about 800° C. to about 1200° C. with the duration ranging from 0.1 msec to 1 sec. When these high-k films (110, 120, . . . , and 190) are annealed by furnace annealing, the annealing temperature ranges from about 600° C. to about 900° C. with the duration ranging from 5 min to 1 hr.

Since these thin high-k films are formed and nitridized layer-by layer, the power of plasma used to nitridize these high-k films can be low to reduce the plasma damage and the nitrogen doping profile can be easily controlled. Moreover, these thin high-k films can be optionally annealed to reduce the number of dangling bonds (i.e. unreactive bonds); a higher boron penetration barrier is thus established. Therefore, the device performance can be improved by a dielectric layer made by these high-k films.

Those parameters described above can be easily optimized by a person skilled in manufacturing semiconductor integrated circuit according to the requirements of the products and many variations of the whole process. Hence those parameters described above are only exemplary of numerous embodiments that may be made of this invention. In short, it is the applicant's intention that the scope of this invention will be limited only by the scope of the appended claims.

What is claimed is:

1. A method of manufacturing a dielectric layer having plural high-k films, comprising:
(a) forming a high-k film on a substrate;
(b) nitridizing the high-k film by a plasma;
(c) repeating step (a) to form another high-k film on the previously formed high-k film; and
(d) repeating step (b) to nitridize the latest formed high-k film.

2. The method of claim 1, wherein a material of these high-k films is silicate or a rare earth metal oxide.

3. The method of claim 1, wherein these high-k films have various thickness of about 0.5 nm to about 2.0 nm.

4. The method of claim 1, wherein the substrate is at a temperature of about 60° C. to about 300° C.

5. The method of claim 1, wherein the RF power of the plasma is about 200 W to 2000 W.

6. The method of claim 1, wherein the plasma is applied in a continuous mode or in a pulse mode.

7. The method of claim 1, wherein the nitridizing step (b) and (d) is performed under a pressure of about 1 mTorr to about 1 Torr.

8. The method of claim 1, further comprising a step (e), between the steps (b) and (c), to anneal the high-k film.

9. The method of claim 8, wherein the annealing step (e) is performed under a temperature of about 600° C. to about 1200° C.

10. The method of claim 8, further comprising a step (f), after step (d), to repeat step (e) to anneal the latest formed high-k film.

11. The method of claim 10, wherein the annealing step (e) is performed under a temperature of about 600° C. to about 1200° C.
